(19) United States
(12) Patent Application Publication
(10) Pub. No.: US 2026/0351842 A1
(43) Pub. Date: Nov. 5, 2026

(54) ANTENNA APPARATUS FOR VEHICLE

(71) Applicants: HYUNDAI MOTOR COMPANY, Seoul (KR); Kia Corporation, Seoul (KR); WINNERCOM CO., LTD., Gimhae-si (KR)

(72) Inventors: Oh Yun Kwon, Hwaseong-si (KR); Deuk Gyeong Kim, Anyang-si (KR); Seong Min Jeong, Suwon-si (KR)

(21) Appl. No.: 19/277,138

(22) Filed: Jul. 22, 2025

(30) Foreign Application Priority Data
Apr. 4, 2025 (KR) 10-2025-0043920

(51) Int. Cl. H01Q 1/40; H01Q 1/00; H01Q 1/24; H01Q 1/32; H01Q 1/52

(52) U.S. Cl. CPC H01Q 1/40; H01Q 1/002; H01Q 1/241; H01Q 1/3275; H01Q 1/526

(57) ABSTRACT

In an embodiment an antenna apparatus includes an antenna module arranged at a roof garnish located at a rear tail side of a vehicle, wherein the antenna module includes a fill cut region formed by an opening on a bottom side of a cellular communication system (CCS) antenna and a rubber pad disposed on a bottom surface of the antenna module and of the fill cut region, the rubber pad configured to prevent moisture from entering the antenna module through the fill cut region.

### CROSS-REFERENCE TO RELATED APPLICATIONS

This application is based on, and claims priority from, Korean Patent Application Number 10-2025-0043920, filed Apr. 4, 2025, the disclosure of which is incorporated by reference herein in its entirety.

### TECHNICAL FIELD

The present disclosure relates to an antenna apparatus for vehicles.

### BACKGROUND

The statements in this section merely provide background information related to the present disclosure and do not necessarily constitute prior art.

Antennas for vehicles are essential for performing various functions such as wireless communication, global navigation satellite system (GNSS), digital broadcast reception, and vehicle-to-everything (V2X) communication.

In recent years, embedded antenna structures in a roof garnish have been proposed to reduce aerodynamic drag and maintain design unity. However, in such structures, the antenna needs to be placed in a limited space between the vehicle body frame and the roof garnish. This poses a limitation to antenna designs with high geometric degrees of freedom.

In a conventional roof garnish-embedded antenna, the radiation pattern of the antenna is distorted, and the performance is degraded due to the proximity of the metal vehicle body. In particular, in the low 617 MHz to 960 MHz frequency band of the antenna, interference with the metal frame reduces the bandwidth and degrades the gain, which can lead to poor communication quality.

Furthermore, there is a limitation that the bandwidth of the antenna becomes difficult to obtain due to increased electromagnetic interference (EMI) between the antenna and the vehicle body frame, due to the limited space inside the roof garnish.

When utilizing the space between the roof garnish and the vehicle body frame to place an antenna, moisture is likely to enter the area. This can lead to corrosion and water leakage, which would damage the vehicle's internal systems.

### SUMMARY

According to at least one embodiment, the present disclosure provides an antenna apparatus of a vehicle, including an antenna module disposed on a roof garnish formed on a rear tail side of the vehicle. The antenna module includes a fill cut region (also called opening region) and a rubber pad (such as a seal or gasket). The fill cut region is formed by opening on the bottom sides of CCS antennas among a plurality of antennas. The rubber pad is disposed on the bottom surface of the antenna module circumferentially of the fill cut region and configured to prevent moisture from entering the antenna module through the fill cut region.

### BRIEF DESCRIPTION OF THE DRAWINGS

FIG. 1 is a diagram illustrating a configuration of an antenna apparatus of a vehicle, according to at least one embodiment of the present disclosure.

FIG. 2 is an exploded view of an antenna module according to at least one embodiment of the present disclosure.

FIG. 3 is an exploded view of an antenna module according to at least one embodiment of the present disclosure.

FIG. 4 is a cross-sectional view of an antenna module according to at least one embodiment of the present disclosure.

FIG. 5 is a diagram illustrating a three-dimensional radiation pattern and a two-dimensional radiation pattern according to at least one embodiment of the present disclosure.

FIG. 6 is a diagram illustrating a frequency improvement region due to a fill cut region of an antenna module according to at least one embodiment of the present disclosure.

FIG. 7 is a graph illustrating antenna gain versus operating frequency of an antenna module according to at least one embodiment of the present disclosure.

### DETAILED DESCRIPTION OF ILLUSTRATIVE EMBODIMENTS

The present disclosure is directed to addressing these issues and improving the performance of an embedded antenna module in a roof garnish.

Further, the present disclosure seeks to prevent moisture from entering the lower side of the antenna module.

The objects of the present disclosure are not limited to those particularly described hereinabove, and the above and other objects that the present disclosure can achieve will be clearly understood by those skilled in the art from the following detailed description.

Hereinafter, some embodiments of the present disclosure will be described in detail with reference to the accompanying drawings. In the following description, like reference numerals preferably designate like elements, although the elements are shown in different drawings. Further, the following description of some embodiments will omit for the purpose of clarity and for brevity, a detailed description of related known components and functions when considered to obscure the subject of the present disclosure.

Various ordinal numbers or alpha codes, such as first, second, i), ii), a), b), etc., are prefixed solely to differentiate one component from the other but not to imply or suggest the substances, order, or sequence of the components. Throughout this specification, when a part ‘includes’ or ‘comprises’ a component, the part is meant to further include other components, to not exclude thereof unless specifically stated to the contrary.

When components are described as ‘connected’, ‘coupled’, or ‘linked’ to another component, they are meant to not only directly ‘connected’, ‘coupled’, or ‘linked’ but also to indirectly ‘connected’, ‘coupled’, or ‘linked’ via one or more additional components.

The terms such as ‘unit’, ‘module’, and the like refer to units for processing at least one function or operation, which may be implemented by hardware, software, or a combination thereof.

Unless the contrary is indicated, the description of one embodiment is intended to apply to other embodiments.

The description of the present disclosure to be presented below in conjunction with the accompanying drawings is intended to describe exemplary embodiments of the present disclosure and is not intended to represent the only embodiments in which the technical idea of the present disclosure may be practiced.

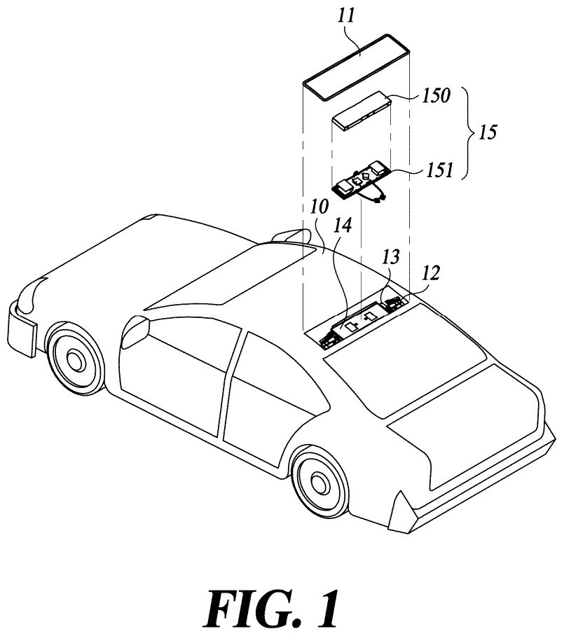

FIG. 1 is a diagram illustrating a configuration of an antenna apparatus of a vehicle, according to at least one embodiment of the present disclosure.

Referring to FIG. 1, the antenna apparatus of the vehicle according to the present disclosure includes an antenna module 15.

The antenna module 15, according to the present disclosure, provides various wireless communication protocols. For example, the wireless communication protocol may include cellular communications using at least one of long-term evolution (LTE), LTE Advance (LTEA), code division multiple access (CDMA), wideband CDMA (WCDMA), universal mobile telecommunications system (UMTS), mobile WiMAX or wireless broadband (WiBro), and global system for mobile communications (GSM) among others. The wireless communication protocol may also include at least one of wireless fidelity (WiFi), Bluetooth, Bluetooth low energy (BLE), Zigbee, near field communication (NFC), magnetic secure transmission, radio frequency (RF), and body area network (BAN), among others.

The antenna module 15, according to the present disclosure, is disposed on the rear tail 12 side of the vehicle. Specifically, a mounting rail 14 is disposed on the rear tail 12 side of the vehicle. Here, the mounting rail 14 may be secured to the rear tail 12 by using a bracket 13.

On top of the antenna module 15 is disposed a roof garnish cap 11. The roof garnish cap 11 is coupled or bonded to the roof panel 10. The roof garnish cap 11 is configured to protect the antenna module 15 from impacts transmitted from an upward direction of the vehicle.

The antenna module 15, according to the present disclosure, may be secured to the mounting rail 14. The mounting rail 14 may include surfaces that are curved upwardly at portions in the forward direction and reverse direction of the vehicle.

The antenna module 15, according to the present disclosure, may have its antenna performance determined based on a separation distance from the upward-bent surfaces of the mounting rail 14.

The gain of the antenna module 15 decreases as its separation distance decreases from surrounding objects, causing frequency interference. Therefore, when securing the antenna module 15 according to the present disclosure to the mounting rail 14, it is possible to position the antenna module 15 at the farthest position away from the upward bent surfaces of the mounting rail 14.

The antenna module 15, according to the present disclosure, includes a lower case 151 and an upper case 150. The lower case 151 and the upper case 150 may be coupled to each other. For example, the lower case 151 and the upper case 150 may be snap-fit coupled.

The antenna module 15 includes a printed circuit board 155 disposed on the lower case 151.

The printed circuit board 155 is mounted with some or all of at least one or more CCS antennas 152, a GNSS antenna 153, and an SXM antenna 154.

The at least one or more CCS antennas 152 according to the present disclosure may include, for example, a count of two of them. However, the number of CCS antennas 152 is not limited, and it may be reduced or increased by the specifications applied and design of the antenna module 15.

The at least one or more CCS antennas 152 according to the present disclosure are disposed on the printed circuit board 155, spaced apart from each other by a quarter of a frequency length. This achieves optimal isolation between two CCS antennas 152 disposed at both ends of the printed circuit board 155.

The GNSS antenna 153, according to the present disclosure, is disposed in a central region on the printed circuit board 155. The GNSS antenna 153, according to the present disclosure, may be configured as a patch-type antenna. However, without limitation in configuration, the GNSS antenna 153 may be configured as a planar rectangular or circular metal plate.

The SXM antenna 154, according to the present disclosure, is positioned between the roof garnish cap 11 and the vehicle body frame (not shown). The SXM antenna 154 may be disposed in the central region of the printed circuit board 155, for example, to satisfy antenna requirement performance from 0 to 90°.

The SXM antenna 154 and the GNSS antenna 153 are disposed in the central region of the printed circuit board 155 for circular polarization characteristics of the antenna's radiation pattern. The SXM antenna 154 and the GNSS antenna 153 radiate frequencies of different bandwidths. Accordingly, the SXM antenna 154 and the GNSS antenna 153 can be disposed at positions adjacent to each other on the printed circuit board 155.

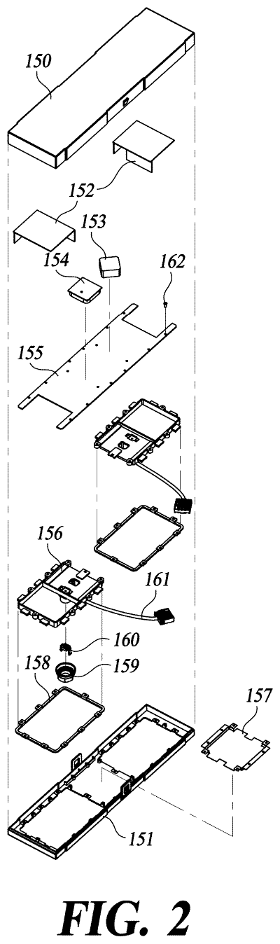

FIG. 2 is an exploded view of the antenna module according to at least one embodiment of the present disclosure.

Referring to FIGS. 1 and 2, the antenna module 15 according to the present disclosure includes some or all of a ground base 156, a shield can 157, a rubber pad 158, an assembling member 159, a stopper 160, and a lead wire assembly 161.

The ground base 156, according to the present disclosure, is disposed on the bottom surface of the printed circuit board 155. The ground base 156 provides ground for the antenna module 15.

The ground base 156 is coupled to the printed circuit board 155 by using a plurality of screws 162.

The ground base 156, according to the present disclosure, may be manufactured based on a zinc alloy (ZnDC-2) material for die casting.

The shield can 157, according to the present disclosure, is disposed in the central region of the lower case 151. The shield can 157 may be disposed at the bottom of the GNSS antenna 153 and the SXM antenna 154, which are mounted in the central region of the printed circuit board 155.

The shield can 157 according to the present disclosure overlays the antennas mounted on the printed circuit board 155, singly or in groups, thereby blocking radio interference from affecting the antennas and protecting the antennas from external impact.

The rubber pad 158, according to the present disclosure, may be fixed to the lower case 151.

The rubber pad 158, according to the present disclosure, provides a watertight structure against moisture entering from the bottom of the antenna module 15. The rubber pad 158 may be fixed in position on the lower case 151 as the lower case 151 and the ground base 156 are coupled together.

The assembling member 159, according to the present disclosure, is configured to secure the antenna module 15 to the mounting rail 14. The assembling member 159 may be, for example, a flange nut. The assembling member 159 may be coupled to a downwardly projecting region of the ground base 156.

The assembling member 159, according to the present disclosure, may generate a coupling force between the ground base 156 and the lower case 151. With the assembling member 159 engaged, the rubber pad 158 may be tightened between the ground base 156 and the lower case 151.

The stopper 160, according to the present disclosure, secures the ground base 156 to the lower case 151.

The lead wire assembly 161, according to the present disclosure, is connected to the printed circuit board 155 via the ground base 156.

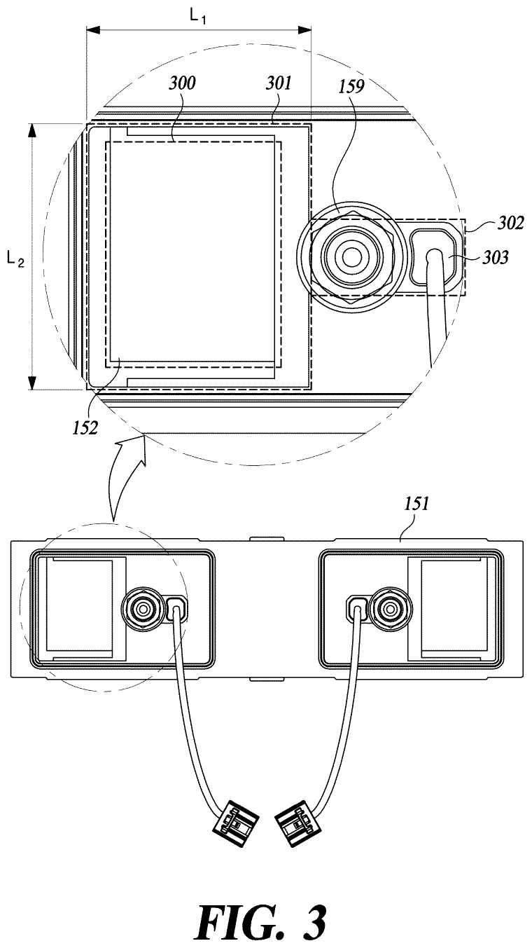

FIG. 3 is an exploded view of the antenna module according to at least one embodiment of the present disclosure.

Referring to FIGS. 1 through 3, the antenna module 15 according to the present disclosure includes a fill cut region at 301 and 302.

The fill cut region at 301 and 302, according to at least one embodiment, is formed by opening on the bottom side of the CCS antennas 152 among the plurality of antennas. Specifically, the fill cut region at 301 and 302 is formed by opening up to the mounting rail 14 from the underside of at least one or more CCS antennas 152. The printed circuit board 155, ground base 156, and lower case 151, according to the present disclosure, are also formed with openings corresponding in size to the fill cut region at 301 and 302.

The fill cut region at 301 and 302 of the antenna module 15, according to the present disclosure, includes a first fill cut region (or first opening region) 301 and a second fill cut region (or second opening region) 302.

The first fill cut region 301, according to at least one embodiment, is formed at the bottom of the CCS antennas 152. The first fill cut region 301 is formed to have a larger size than an antenna region 300 formed by each of the CCS antennas 152. This is because, for example, the fill cut region of a similar size to the antenna region 300 may cause antenna performance degradation.

The first fill cut region 301, according to at least one embodiment, has a transverse length and a longitudinal length determined based on the lowest of the frequency wavelengths of the at least one or more CCS antennas 152.

For example, according to at least one embodiment, the sum of the transverse length L₁ and the longitudinal length L₂ of the first fill cut region 301 is longer than a quarter length (mm) of the lowest of the frequency wavelengths of the CCS antennas 152. For example, if the lowest frequency wavelength of the CCS antennas 152 is 617 MHz, the corresponding frequency wavelength λ has a length of 486 mm. Accordingly, the sum of the transverse length L₁ and the longitudinal length L₂ of the first fill cut region 301 needs to be determined to be 122 mm or longer.

The second fill cut region 302, according to at least one embodiment, is formed by extending from the first fill cut region 301.

The second fill cut region 302, according to at least one embodiment, includes the regions where the assembling member 159 and a lead wire exit 303 are located. Specifically, the second fill cut region 302 includes a mounting region (not shown) and a lead wire region (not shown).

The mounting region, according to at least one embodiment, refers to a region corresponding to a location where the assembling member 159 is fastened. The mounting region may be a region at a location adjacent to the first fill cut region 301.

The assembling member 159, according to at least one embodiment, electrically connects the ground base 156 and the vehicle body ground. Therefore, placing the mounting region adjacent to the first fill cut region 301 does not affect the performance of the antenna module 15.

The mounting region, according to at least one embodiment, has a size corresponding to the size or diameter of the assembling member 159.

The lead wire region, according to at least one embodiment, is a region on the ground base 156 through which the lead wire assembly 161 is connected to the printed circuit board 155. The lead wire region may be formed at a location in an extending direction from the first fill cut region 301.

The lead wire region may be formed at a location from the mounting region and in a direction away from the first fill cut region 301, to space the lead wire that affects the performance of the CCS antennas 152 by a predetermined distance from the first fill cut region 301.

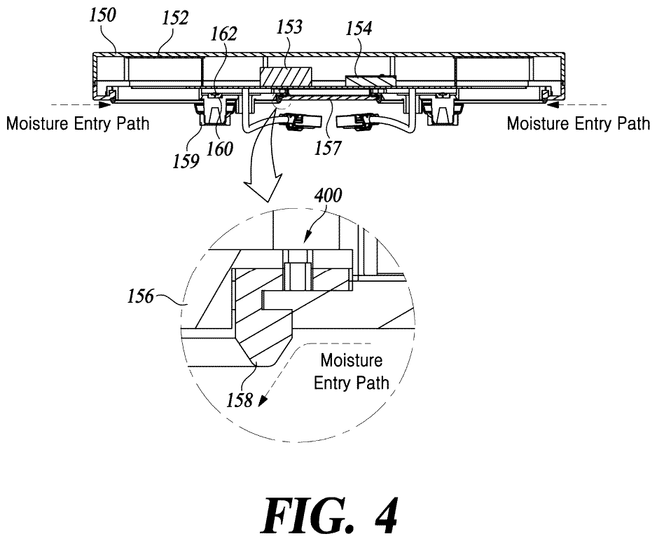

FIG. 4 is a cross-sectional view of the antenna module according to at least one embodiment of the present disclosure.

Referring now to FIGS. 1 through 4, the antenna module 15 according to the present disclosure is provided with the rubber pad 158 for preventing moisture from entering the fill cut region at 301 and 302 formed on the underside.

The rubber pad 158 has a shape that partially protrudes downwardly relative to the bottom surface of the lower case 151.

The rubber pad 158 forms a watertight structure against moisture that may enter the fill cut region at 301 and 302 around the lower case 151, depending on the driving condition of the vehicle. For example, moisture that is deposited on the bottom surface of the lower case 151 may enter the fill cut region at 301 and 302 formed on the underside of the CCS antennas 152 based on the behavior of the vehicle. In this case, the rubber pad 158 forms a step protruding downwardly by a predetermined length relative to the bottom surface of the lower case 151. The rubber pad 158 can prevent moisture around the bottom surface of the lower case 151 from entering the fill cut region.

The rubber pad 158 is coupled to the ground base 156. The rubber pad 158 may be secured to the ground base 156 by using a fastening member such as a bolt (not shown). The rubber pad 158 may include a securing hole 400 for securing the ground base 156 with the fastening member.

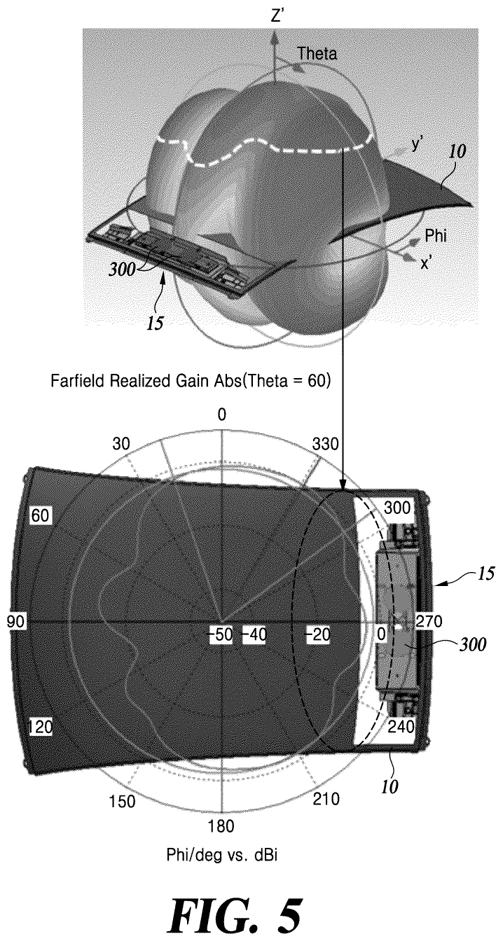

FIG. 5 is a diagram illustrating a three-dimensional radiation pattern and a two-dimensional radiation pattern according to at least one embodiment of the present disclosure.

Referring to FIGS. 1 through 5, radiation characteristics of the antenna module 15 according to the present disclosure can be explained.

The three-dimensional radiation pattern of the antenna module 15 illustrated in FIG. 5 exhibits the radiation pattern of the antenna module 15 disposed on the roof panel 10 of the vehicle. The three-dimensional radiation pattern indicates the spatial distribution of electromagnetic waves radiated by the antenna module 15, and shows the radiation characteristics in the theta (elevation) and phi (azimuth) directions in a spherical coordinate system.

The three-dimensional radiation pattern illustrates how electromagnetic waves radiating from the antenna module 15 spread upward and sideways relative to the Z′-axis (theta direction). The dashed region is where the radiation intensity fluctuates in a particular direction, which is improved by a more uniform radiation pattern with the fill cut region at 301 and 302 applied.

The two-dimensional radiation pattern illustrated in FIG. 5 exhibits a two-dimensional radiation pattern projected from a viewpoint on top of the vehicle.

The two-dimensional radiation pattern is the result of projecting the three-dimensional radiation pattern from the top of the vehicle and shows the radiation gain as a function of the value of phi (azimuth). The two-dimensional radiation pattern is a graph of radiation gain from 0° to 360° of phi (azimuth) with theta=60° fixed.

By using the three-dimensional and two-dimensional radiation patterns, the antenna module 15 according to at least one embodiment of the present disclosure exhibits the signal radiation characteristics of the antenna module 15 in the vehicle's right (0°), front (90°), left (180°), and rear (270°) directions. In the vehicle's left (180°) and rear (270°) directions, the radiation gain is relatively low, while in the right (0°) and front (90°) directions, the radiation pattern is relatively balanced, and the radiation gain may increase in certain frequency bands.

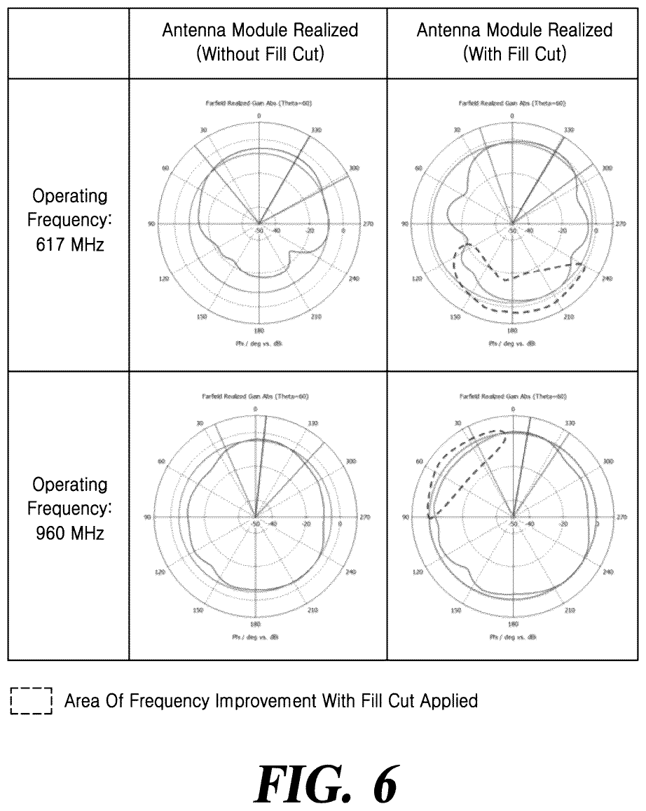

FIG. 6 is a diagram illustrating a frequency improvement region thanks to a fill cut region of an antenna module according to at least one embodiment of the present disclosure.

Referring to FIGS. 1 through 6, the difference in comparative radiation characteristics can be explained with and without the application of the fill cut region at 301 and 302 of the antenna module 15.

FIG. 6 illustrates antenna radiation patterns at operating frequencies of 617 MHz and 960 MHz, wherein the left side shows the radiation patterns when the fill cut region at 301 and 302 is not applied to the antenna module 15 (without fill cut) and the right side shows the radiation patterns when the fill cut region at 301 and 302 is applied to the antenna module 15 (with fill cut), respectively.

Where the fill cut region at 301 and 302 is not applied to the antenna module 15, the metal vehicle body located underneath the vehicle's roof garnish cap 11 will interfere with the radiation pattern of the antenna module 15, limiting and preventing the signal from radiating strongly in certain directions. This causes the radiation balance in the 617 MHz and 960 MHz bands to be collapsed and the overall gain to be reduced.

On the other hand, when the fill cut is applied to the antenna module 15, it can be seen that the radiation pattern is formed more uniformly than ever before, and the signal radiation characteristics in certain directions are improved. In particular, in the 617 MHz and 960 MHz bands, differences occur in the radiation pattern before and after applying the fill cut region at 301 and 302, which is centered on the region indicated by the dotted lines, indicating that the radiation performance in those frequency bands can be improved by applying the fill cut region at 301 and 302 to the antenna module 15.

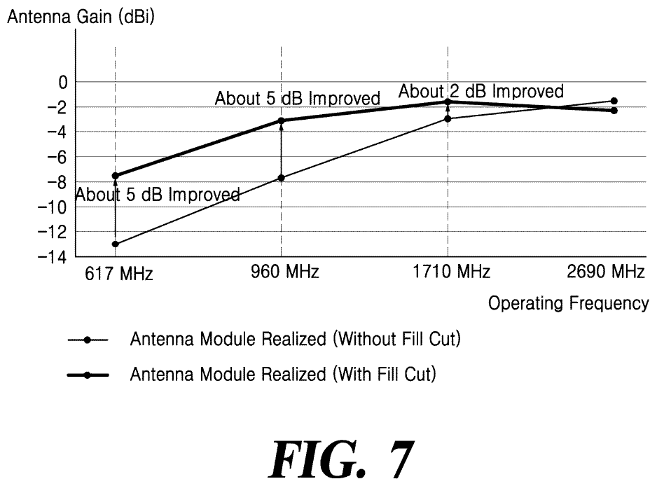

FIG. 7 is a graph illustrating antenna gain versus operating frequency of an antenna module according to at least one embodiment of the present disclosure.

Referring to FIGS. 1 through 7, the antenna gain of the antenna module 15 can be explained as a function of the operating frequency of the antenna module 15.

FIG. 7 illustrates the change in performance with and without the fill cut region at 301 and 302 in the antenna module 15. Specifically, this graph shows the results of measuring antenna gain in key frequency bands of 617 MHz, 960 MHz, 1710 MHz, and 2690 MHz. By comparing the two cases that are without the fill cut region at 301 and 302 (thin lines) and with the fill cut region at 301 and 302 (thick lines), the effect of the fill cut region at 301 and 302 of antenna module 15 on antenna performance can be compared.

In the low-frequency band (617 MHz to 960 MHz), the difference in gain thanks to the application of the fill cut region at 301 and 302 is the largest. When the fill cut region at 301 and 302 is applied to the antenna module 15, an antenna gain effect of about 5 dB in the low frequency band (617 MHz to 960 MHz) is seen. This is because the influence of the metal vehicle body on the radiation characteristics of the antenna is reduced by the fill cut structure, resulting in an increase in radiation gain in the low frequency band. Even at 960 MHz, an antenna gain improvement of about 5 dB is achieved by the application of the fill cut region at 301 and 302.

On the other hand, in the high-frequency band of 1710 MHz or higher, the difference in gain due to the application of the fill cuts becomes relatively small, with a gain improvement of about 2 dB at 1710 MHz. This may be because the effect of the fill cut structure is less affected by the metallic vehicle body in the high-frequency region than in the low-frequency region.

In at least one embodiment, the antenna apparatus of the vehicle has the effect of improving the performance of the roof garnish-embedded antenna module.

In at least one embodiment, the antenna apparatus of the vehicle has the effect of preventing moisture from entering the lower side of the antenna module.

Although exemplary embodiments of the present disclosure have been described for illustrative purposes, those skilled in the art will appreciate that various modifications, additions, and substitutions are possible without departing from the idea and scope of the claimed invention. Therefore, exemplary embodiments of the present disclosure have been described for the sake of brevity and clarity. The scope of the technical idea of the embodiments of the present disclosure is not limited by the illustrations. Accordingly, one of ordinary skill would understand that the scope of the claimed invention is not to be limited by the above explicitly described embodiments but by the claims and equivalents thereof.

What is claimed is:

1. An antenna apparatus comprising:
an antenna module arranged at a roof garnish located at a rear tail side of a vehicle,
wherein the antenna module comprises:
a fill cut region formed by an opening on a bottom side of a cellular communication system (CCS) antenna; and
a rubber pad disposed on a bottom surface of the antenna module in a circumferential direction of the fill cut region to prevent moisture from entering the antenna module through the fill cut region.

2. The antenna apparatus of claim 1, wherein the antenna module further comprises:
an upper case forming a top surface of the antenna module and configured to protect the CCS antenna and a plurality of antennas from an impact from outside of the vehicle;
a lower case snap-fit coupled to the upper case; and
a ground base configured to secure the lower case and a printed circuit board, and having an aperture shaped corresponding to the fill cut region, and
wherein the printed circuit board is screwed to a top surface of the ground base and is configured to hold the plurality of antennas.

3. The antenna apparatus of claim 2, wherein the fill cut region is the opening from the bottom side of the CCS antenna to a mounting rail connected to the rear tail.

4. The antenna apparatus of claim 3, wherein the fill cut region is the opening that extends from the CCS antenna through the printed circuit board, the ground base and the lower case to the mounting rail.

5. The antenna apparatus of claim 1, wherein the CCS antenna comprise two CCS antennas disposed on opposite ends of the antenna module and spaced apart from each other by a distance of λ/4.

6. The antenna apparatus of claim 1, wherein the antenna module further comprises a global navigation satellite system (GNSS) antenna and an SXM antenna.

7. The antenna apparatus of claim 6, wherein the GNSS antenna and the SXM antenna are disposed adjacent to each other in a central region of the antenna module.

8. The antenna apparatus of claim 1, wherein the fill cut region comprises:
a first fill cut region formed at the bottom side of the CCS antenna and having a size, in top view, larger than an antenna region of the CCS antenna; and
a second fill cut region extending from the first fill cut region, and comprising regions in which an assembling member and a lead wire exit are located.

9. The antenna apparatus of claim 8, wherein the first fill cut region has a transverse length and a longitudinal length that are determined based on a lowest frequency wavelength of frequency wavelengths of the CCS antenna.

10. The antenna apparatus of claim 8, wherein the second fill cut region comprises:
a mounting region that is coupled with the assembling member and located at a position adjacent to the first fill cut region; and
a lead wire region formed for through connection of the lead wire, and formed at a location in an extending direction from the mounting region relative to the first fill cut region.

11. The antenna apparatus of claim 10, wherein the mounting region has a size corresponding to a size or diameter of the assembling member.

12. The antenna apparatus of claim 2, wherein the rubber pad is assembled with the lower case, and secured by engagement of the ground base with the lower case.

13. The antenna apparatus of claim 12, wherein the rubber pad is configured to remain protruded downwardly from a bottom surface of the lower case to prevent moisture from entering the antenna module through a moisture entry path on the lower case.

14. An antenna apparatus comprising:
an antenna module comprising:
an upper case forming a top surface of the antenna module;
a lower case connected to the upper case and forming a bottom surface of the antenna module; and
a cellular communication system (CCS) antenna; and
a mounting rail,
wherein a fill cut region, which is an opening region, extends from a bottom side of the CCS antenna through the lower case to the mounting rail, and
wherein a seal is circumferentially located at an opening in the lower case, the opening corresponding to the opening region, and
wherein the seal is configured to prevent moisture from entering the antenna module through the opening region.

15. The antenna apparatus of claim 14, further comprising:
a roof garnish located at roof of a vehicle,
wherein the roof garnish is located above the antenna module, and
wherein is the mounting rail of the vehicle.

16. An antenna module comprising:
an upper case forming a top surface of the antenna module;
a lower case connected to the upper case and forming a bottom surface of the antenna module;
two cellular communication system (CCS) antennas arranged at opposite ends of the antenna module;
a fill cut region, which is an opening region, located at a bottom side of each CCS antenna and extending through the lower case; and
two seals located at the opening regions at the bottom surface of the antenna module, each seal lining an opening in the lower case and corresponding to a respective opening region.

17. The antenna module of claim 16, wherein the CCS antennas are spaced apart from each other by a distance of λ/4.

18. The antenna module of claim 16, further comprising a global navigation satellite system (GNSS) antenna and an SXM antenna, wherein the GNSS antenna and the SXM antenna are disposed adjacent to each other in a central region of the antenna module between the two CCS antennas.

19. The antenna module of claim 18, further comprising a shield located on the bottom surface of the antenna module in the central region between the two seals.

20. The antenna module of claim 16, wherein each opening region comprises:
a first opening region having, in top view, a size larger than an antenna region of each CCS antennas; and
a second opening region directly abutting the opening cut region and extending the first opening region, the second opening region comprising regions in which an assembling member configured for mounting the antenna module to a mounting rail and a lead wire exit are located.
